(19) United States
(12) Patent Application Publication
(10) Pub. No.: US 2024/0369927 A1
(43) Pub. Date: Nov. 7, 2024

(54) POSITIVE PHOTORESIST COMPOSITION, NEGATIVE PHOTORESIST PATTERN LITHOGRAPHY PROCESS METHOD AND PHOTORESIST FILM MADE THEREFROM

(71) Applicant: Advanced Echem Materials Company Limited, Taoyuan (TW)

(72) Inventors: Kuo Chu Yeh, Taoyuan (TW); Che Wei Chang, Taoyuan (TW); Tz Jin Yang, Taoyuan (TW); Ming Che Chung, Taoyuan (TW)

(21) Appl. No.: 18/654,024

(22) Filed: May 3, 2024

(30) Foreign Application Priority Data
May 5, 2023 (TW) 112116844

(51) Int. Cl. G03F 7/039; C08G 73/10; C09D 179/08; G03F 7/00; G03F 7/16

(52) U.S. Cl. CPC G03F 7/039; C08G 73/106; C09D 179/08; G03F 7/0035; G03F 7/161; G03F 7/168

(57) ABSTRACT

The disclosure provides a positive photoresist composition, comprising: a (A) polyimide resin, a (B) photo active compound and a (C) solvent. The (A) polyimide resin is obtained by a polymerization reaction of a (a) diamine and a (b) tetracarboxylic dianhydride, and has a structural unit of formula (1); wherein, Ar¹ in the formula (1) is a tetravalent organic group, Ar² is a bivalent organic group, and Ar¹ is a group of formula (B-1), formula (B-2), formula (B-3) or a combination thereof, and Ar² is at least a group of formula (A-1), formula (A-2) or a combination thereof. Furthermore, Ar² can further be a group of formula (A-3), formula (A-4), formula (A-5) or a combination thereof. The present disclosure further provides a negative photoresist pattern lithography process method and a photoresist pattern thereof.

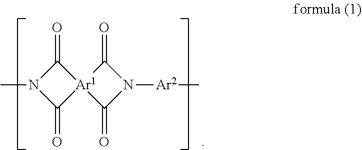

### FIELD OF THE INVENTION

The present disclosure relates to a positive photoresist composition, and in particular to a positive photoresist composition that can be used in a negative photoresist pattern lithography process, and to a negative photoresist pattern lithography process method.

### BACKGROUND OF THE INVENTION

Due to the increasing demand for digital cameras and mobile phone cameras, the lens module is developing towards high resolution; where, for example, a color filter array (CFA) is a key component that determines the performance of the lens module. In the lithography process, a negative photoresist has better chemical resistance, heat resistance, and etching resistance than a positive photoresist because after exposure the negative photoresist film surface is a cross-linked structure. However, the negative photoresist used in the traditional CFA is difficult to meet the high-resolution requirement, so manufacturers are devoting themselves to the development of negative photoresist materials and lithography process technology.

### SUMMARY OF THE INVENTION

One of objectives of some embodiments of the present invention is to provide a positive photoresist composition.

Another one of objectives of some embodiments of the present invention is to provide a positive photoresist composition suitable for a negative photoresist pattern lithography process.

A further one of objectives of some embodiments of the present invention is to provide a negative photoresist film with high pattern resolution.

In some embodiments of the present invention, the positive photoresist composition comprises (A) a polyimide resin, (B) a photo active compound, and (C) a solvent. The (A) polyimide resin is obtained by conducting a polymerization reaction of a (a) diamine and a (b) tetracarboxylic dianhydride, and has a structural unit of formula (1)

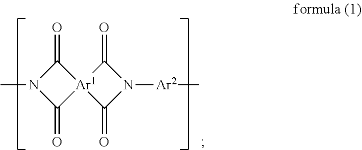

wherein, Ar¹ in the formula (1) is a tetravalent organic group, Ar² is a bivalent organic group, and Ar¹ is a group of formula (B-1), formula (B-2), formula (B-3) or a combination thereof

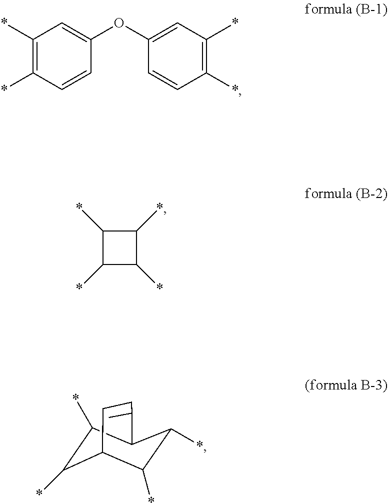

* indicates a bonding position; Ar² in the formula (1) includes a group of formula (A-1), formula (A-2) or a combination thereof

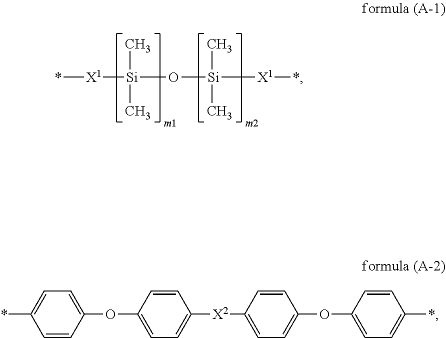

wherein, m1 and m2 in the formula (A-1) are each an integer of 1-3, and X¹ is each an alkylene or phenylene group with a carbon number of 1 to 5; wherein, when X¹ is an alkylene group with a carbon number of 1 to 5, any —CH₂— in the alkylene group with the carbon number of 1 to 5 can be substituted by —NH—; X² in the formula (A-2) is a hydrocarbyl group with a carbon number of 1 to 10, —O—, —S—, —SO₂—, —NH—, —C(CF₃)₂— or

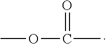

In an embodiment of the present invention, the aforementioned Ar² further includes a group of formula (A-3), formula (A-4), formula (A-5) or a combination thereof

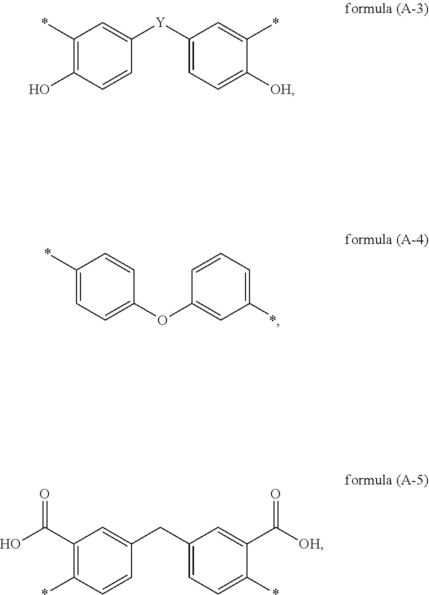

wherein, Y in the formula (A-3) is —C(CH₃)₂—, —C(CF₃)₂—, —CH₂—, —O—, —S— or —SO₂—; and * indicates a bonding position.

In an embodiment of the present invention, the aforementioned (a) diamine includes a (a-1) diamine and a (a-2) diamine; wherein the (a-1) diamine is a diamine having a silicon-oxygen bond, and is a compound of formula (I-1); and the (a-2) diamine is a diamine having four benzene rings, and is a compound of formula (I-2):

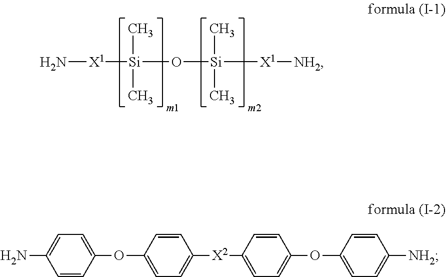

wherein, m1 and m2 in the formula (I-1) are each an integer of 1-3, and X¹ is each an alkylene or phenylene group with a carbon number of 1 to 5; wherein, when X¹ is an alkylene group with a carbon number of 1 to 5, any —CH₂— in the alkylene group with the carbon number of 1 to 5 can be substituted by —NH—; X² in the formula (I-2) is a hydrocarbyl group with a carbon number of 1 to 10, —O—, —S—, —SO₂—, —NH—, —C(CF₃)₂— or

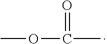

In an embodiment of the present invention, the aforementioned (a) diamine further includes a (a-3) diamine; the (a-3) diamine is a diamine having a phenol structure, and is a compound of formula (I-3)

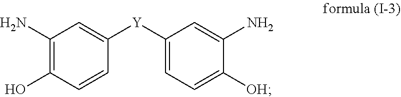

wherein, Y in the formula (1-3) is —C(CH₃)₂—, —C(CF₃)₂—, —CH₂—, —O—, —S— or —SO₂—.

In an embodiment of the present invention, the aforementioned (A) polyimide resin has a weight average molecular weight of 5,000-50,000.

In an embodiment of the present invention, the aforementioned (B) photo active compound is quinone diazide sulfonic acid, a quinone diazide sulfonic acid derivative or a combination thereof; and when an amount of the (A) polyimide resin is 100 parts by weight, an amount of the (B) photo active compound is 10-150 parts by weight.

In an embodiment of the present invention, the aforementioned (C) solvent is N-methylpyrrolidone, γ-butyrolactone, ethyl lactate, N,N-dimethylformamide, N,N-dimethyl acetamide or a combination thereof, and the (C) solvent accounts for 50-90 wt % of the positive photoresist composition in weight percentage.

Some embodiments of the present invention further provide a negative photoresist pattern lithography process method, comprising the following steps: coating the aforementioned positive photoresist composition on a substrate; heating the positive photoresist composition and forming a film layer; patterning the film layer and forming a positive photoresist pattern; coating a negative photoresist composition on the substrate; heating the negative photoresist composition; and patterning the film layer and forming a negative photoresist pattern.

In an embodiment of the present invention, the aforementioned step of patterning the film layer and forming the positive photoresist pattern further comprises exposing and developing the film layer, and the step of patterning the film layer and forming the negative photoresist pattern further comprises exposing and developing the film layer, with the positions of the two exposures being the same.

In an embodiment of the present invention, the aforementioned step of heating the positive photoresist composition further includes baking at 100-130° C., and the heating the negative photoresist composition further includes baking at 80-120° C.

In an embodiment of the present invention, the aforementioned step of patterning the film layer and forming the positive photoresist pattern further comprises allowing the positive photoresist pattern to define a first region and a second region on the substrate.

In an embodiment of the present invention, the aforementioned step of coating the negative photoresist composition on the substrate further comprises distributing the negative photoresist composition in the second region.

In an embodiment of the present invention, the aforementioned step of coating the negative photoresist composition on the substrate further comprises distributing the negative photoresist composition in the first region, wherein the negative photoresist composition distributed in the first region covers the positive photoresist pattern.

In an embodiment of the present invention, the aforementioned step of coating the negative photoresist composition on the substrate further comprises distributing the negative photoresist composition in the second region; and the step of patterning the film layer and forming the negative photoresist pattern further comprises exposing the negative photoresist composition distributed in the second area to form the negative photoresist pattern.

In an embodiment of the present invention, the aforementioned step of patterning the film layer and forming the negative photoresist pattern further comprises developing with an alkaline aqueous solution, and removing the positive photoresist pattern.

In an embodiment of the present invention, the aforementioned negative photoresist pattern lithography process method further includes preparing a positive photoresist composition by using a (A) polyimide resin, a (B) photo active compound and a (C) solvent; wherein the (A) polyimide resin has a structural unit of formula (1), Ar¹ is a tetravalent organic group, Ar² is a bivalent organic group, and Ar¹ is a group of formula (B-1), formula (B-2), formula (B-3) or a combination thereof, and Ar² contains a group of formula (A-1), formula (A-2) or a combination thereof

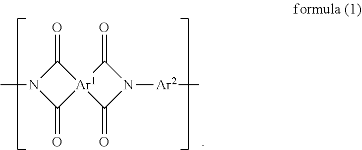

In an embodiment of the present invention, the aforementioned step of preparing the positive photoresist composition further comprises conducting a polymerization reaction of a (a) diamine and a (b) tetracarboxylic dianhydride to provide a (A) polyimide resin.

The positive photoresist composition of the present invention adopts the (A) polyimide resin obtained by conducting the polymerization reaction of the (a) diamine and the (b) tetracarboxylic dianhydride, so it is suitable for the negative photoresist pattern lithography process. In the present invention, the positive photoresist composition is adopted in the negative photoresist pattern lithography process, so that the prepared negative photoresist film can have high pattern resolution.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

FIG. 1 is a schematic flow chart of a positive photoresist pattern lithography process according to an embodiment of the present invention.

FIG. 2 is a schematic flow chart of a negative photoresist pattern lithography process according to an embodiment of the present invention.

FIGS. 3A-3E are schematic diagrams of the operation of the negative photoresist pattern lithography process according to an embodiment of the present invention.

### DETAILED DESCRIPTION OF PREFERRED EMBODIMENTS

Unless otherwise defined, the “hydrocarbyl group” referred in this disclosure means an organic group composed only of carbon and hydrogen, for example an alkyl group, an alkenyl group or an alkynyl group. Furthermore, the hydrocarbyl group may be a linear hydrocarbyl group, a branched hydrocarbyl group, or a cyclic hydrocarbyl group. A “tetravalent organic group” is an organic group having four bonding positions, and the “tetravalent organic group” can form four chemical bonds via the four bonding positions. A “bivalent organic group” is an organic group having two bonding positions, and the “bivalent organic group” can form two chemical bonds via the two bonding positions. A “photoresist film” can be formed with or without a “pattern” or “picture”, and a “photoresist film pattern” means a photoresist film formed with or having a “pattern” or “picture”. In this disclosure, the “pattern” and the “picture” have substantially the same meaning. In this disclosure, the “photoresist pattern” and the “photoresist film pattern” have substantially the same meaning, and the former is more used for emphasizing the pattern of a photoresist film. In this disclosure, in the preparation of the photoresist film, what is obtained by coating and heating is referred to as the “film layer”. A “film face” can be the surface of the photoresist film or the surface of the film layer.

### Positive Photoresist Composition

The present invention provides a positive photoresist composition, which can be used for the preparation of a positive photoresist film; as well as a positive photoresist pattern lithography process and a negative photoresist pattern lithography process. The positive photoresist composition of the present invention comprises a (A) polyimide resin, a (B) photo active compound and a (C) solvent. In some embodiments of the present invention, the (A) polyimide resin is obtained by conducting a polymerization reaction of a (a) diamine and a (b) tetracarboxylic dianhydride, has a weight average molecular weight of 5,000-50,000, and its weight average molecular weight is preferably 10,000-40,000, and more preferably 25,000-35,000. The (A) polyimide resin can have a structural unit of formula (1), wherein, Ar¹ is a tetravalent organic group, Ar² is a bivalent organic group, and Ar¹ can be a group of formula (B-1), formula (B-2), formula (B-3) or a combination thereof, and Ar² includes a group of formula (A-1), formula (A-2) or a combination thereof. Furthermore, Ar² can further include a group of formula (A-3), formula (A-4), formula (A-5) or a combination thereof. That is, in the structural units of formula (1) of the (A) polyimide resin, there should be the structural unit where Ar² is the group of formula (A-1) or formula (A-2). In addition to this, the Ar² of the remaining structural units can be the group of formula (A-3), formula (A-4), or formula (A-5). The Ar² of the structural units of the (A) polyimide resin can each be a group of either formula (A-1) or formula (A-2). * indicates a bonding position:

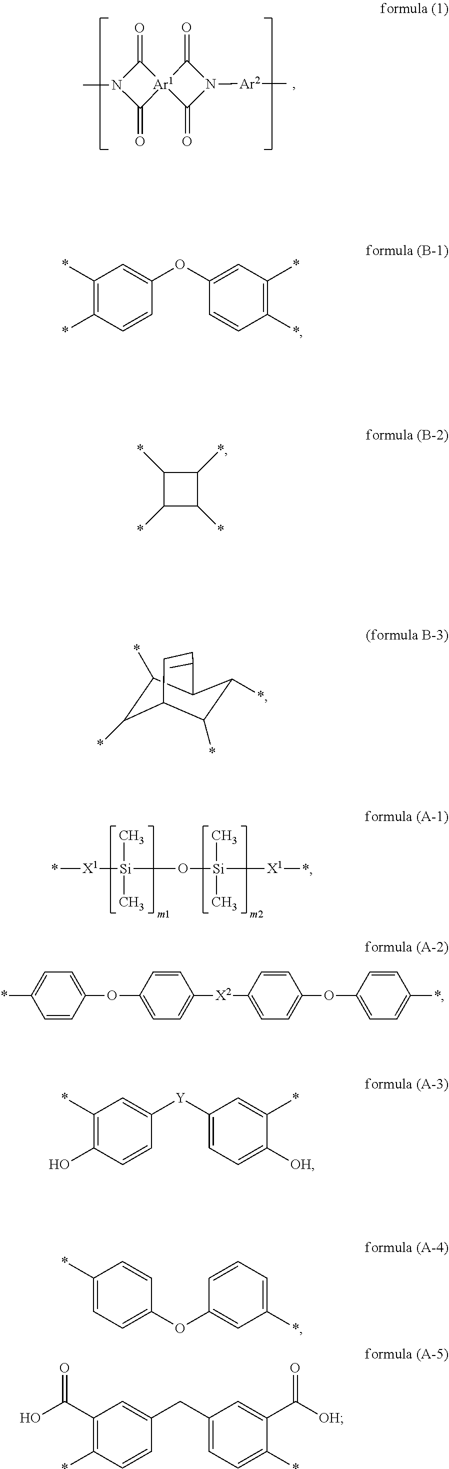

wherein, m1 and m2 in the formula (A-1) can each be an integer of 1-3, and X¹ can each be an alkylene or phenylene group with a carbon number of 1 to 5; wherein, when X¹ is an alkylene group with a carbon number of 1 to 5, any —CH₂— in the alkylene group with the carbon number of 1 to 5 can be substituted by —NH—; X² in the formula (A-2) can be a hydrocarbyl group with a carbon number of 1 to 10, —O—, —S—, —SO₂—, —NH—, —C(CF₃)₂— or

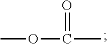

Y in the formula (A-3) can be —C(CH₃)₂—, —C(CF₃)₂—, —CH₂—, —O—, —S— or —SO₂—; and * indicates a bonding position. The (A) polyimide resin, the (B) photo active compound, and the (C) solvent are further mixed, dissolved or evenly dispersed in an appropriate ratio to obtain a positive photoresist composition. For example, relative to 100 parts by weight of the (A) polyimide resin, an amount of the (B) photo active compound is 10-150 parts by weight, preferably 20-80 parts by weight, and more preferably 30-60 parts by weight. There is no particular limitation on the (C) solvent, as long as it can dissolve the (A) polyimide resin and the components in the positive photoresist composition of the present invention, and does not react with the components in the positive photoresist composition. Preferably, the (C) solvent can be a solvent used when the (A) polyimide resin is synthesized (described hereafter). A film formed by the positive photoresist composition of the present invention can be insoluble in the negative photoresist composition or the solvent used for a negative photoresist (described hereafter), and when the negative photoresist pattern lithography process is carried out, the film formed by the positive photoresist composition and an unexposed negative photoresist composition can be peeled off simultaneously during development.

### (A) Polyimide Resin

The (A) polyimide resin can be obtained by a polymerization reaction of a (a) diamine and a (b) tetracarboxylic dianhydride. A molar ratio of the (a) diamine to the (b) tetracarboxylic dianhydride can be 0.5-1.2:1, and preferably 0.9-1.1:1. The (a) diamine and the (b) tetracarboxylic dianhydride are described in detail below.

### (a) Diamine

The (a) diamine at least includes a (a-1) diamine and a (a-2) diamine.

(a-1) Diamine

The (a-1) diamine is a diamine having a silicon-oxygen bond, and can be a compound of formula (I-1)

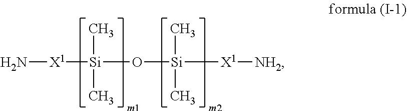

m1 and m2 in the formula (I-1) are each an integer of 1-3. m1 and m2 are preferably each 1. X¹ is each an alkylene or phenylene group with a carbon number of 1 to 5, wherein, when X¹ is an alkylene group with a carbon number of 1 to 5, any —CH₂— in the alkylene group with the carbon number of 1 to 5 can be substituted by —NH—. X¹ is preferably an alkylene group with a carbon number of 1 to 5 or —CH₂CH₂NHCH₂—, and more preferably a propylene group. In some embodiments of the present invention, the (a-1) diamine can be a compound of formula (I-1-1)

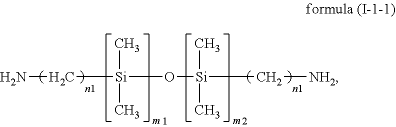

m1 and m2 in the formula (I-1-1) are each an integer of 1-3, and preferably each 1. n1 and n2 are each an integer of 1-5, preferably each an integer of 1-3, and more preferably each 3. Specific examples of the (a-1) diamine include, but are not limited to, 1,3-bis(3-aminopropyl)-1,1,3,3-tetramethyldisiloxane, 1,3-bis-(2-aminoethylaminomethyl) tetramethyldisiloxane, 1,3-bis(4-aminophenyl)-1,1,3,3-tetramethyldisiloxane or a combination thereof, wherein 1,3-bis(3-aminopropyl)-1,1,3,3-tetramethyldisiloxane is preferred.
(a-2) Diamine

The (a-2) diamine is a diamine with four benzene rings, and can be a compound of formula (I-2)

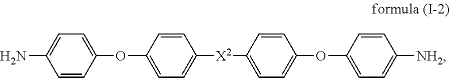

X² in the formula (I-2) is a hydrocarbyl group with a carbon number of 1 to 10, —O—, —S—, —SO₂—, —NH—, —C(CF₃)₂— or

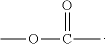

X² is preferably an alkylene group with a carbon number of 1 to 5 or —C(CF₃)₂—, and more preferably an alkylene group with a carbon number of 3. X² is an alkylene group with a carbon number of 3, and a specific example thereof is for example —C(CH₃)₂—. Specific examples of the (a-2) diamine include, but are not limited to, 2,2′-Bis[4-(4-aminophenoxy)phenyl]propane (BAPP), 2,2-bis[4-(4-aminophenoxy)phenyl]hexafluoropropane, bis(4-(4-aminophenoxy)phenyl)sulfone or a combination thereof, wherein 2,2′-Bis[4-(4-aminophenoxy)phenyl]propane is preferred.

The (a) diamine can further include a (a-3) diamine. The (a-3) diamine is a diamine having a phenol structure, and can be a compound of formula (I-3)

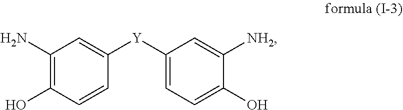

Y in the formula (I-3) is —C(CH₃)₂—, —C(CF₃)₂—, —CH₂—, —O—, —S— or —SO₂—, and preferably —C(CH₃)₂—. Specific examples of the (a-3) diamine include, but are not limited to, 2,2-bis(3-amino-4-hydroxyphenyl) propane (BAHPP), 2,2-bis(3-amino-4-hydroxyphenyl) hexafluoropropane, 2,2-bis(3-amino-4-hydroxyphenyl)sulfone or a combination thereof, wherein 2,2-bis(3-amino-4-hydroxyphenyl) propane is preferred.

The (a) diamine can further include a (a-4) diamine, and/or a (a-5) diamine. There is no limitation on the (a-4) diamine, and the diamine can be appropriately selected as desired. In some embodiments of the present invention, it can have, for example, a functional group of formula (I-4). Specific examples of the (a-4) diamine include, but are not limited to, 3,4′-diaminodiphenyl ether, 3,4-diaminodiphenyl ether, 4,4-diaminodiphenyl ether, 3,4-diaminodiphenylsulfone, 4,4-diaminodiphenylsulfone, bis[4-(3-aminophenoxy)phenyl]sulfone, bis(4-amino-3-carboxyphenyl) methane or a combination thereof, wherein 3,4′-diaminodiphenyl ether is preferred. The (a) diamine can further include a (a-5) diamine. There is no limitation on the (a-5) diamine, and the diamine can be appropriately selected as desired. In some embodiments of the present invention, it can contain, for example, a functional group of formula (I-5). Specific examples of the (a-5) diamine include, but are not limited to, bis(4-amino-3-carboxyphenyl) methane, 3,5-diaminobenzoic acid, 6,6′-bisamino-3,3′-methoxydibenzoic acid. The (a) diamine can further include a (a-6) diamine, and specific examples thereof include, but are limited to not 3,3′-dicarboxyl-4,4′-diaminodiphenylmethane.

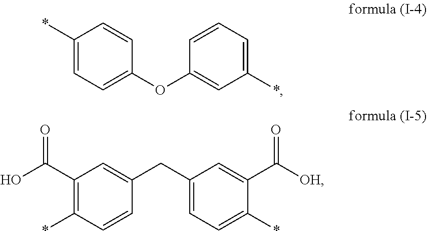

* indicates a bonding position.

### (b) Tetracarboxylic Dianhydride

There is no limitation on the (b) tetracarboxylic dianhydride, and appropriate tetracarboxylic dianhydride can be selected according to requirements. Specific examples of the (b) tetracarboxylic dianhydride include, but are not limited to 3,3′,4,4′-diphenyl ether tetracarboxylic dianhydride (ODPA), Bicyclo[2.2.2]oct-7-ene-2,3,5,6-tetracarboxylic dianhydride (BTA), 1,2,4,5-cyclohexane tetracarboxylic dianhydride, 5-(2,5-dioxotetrahydrofuran)-3-methyl-3-cyclohexene-1,2-dicarbonic anhydride, 3,3′,4,4′-benzophenone tetracarboxylic dianhydride, 2,3,3′,4′-diphenylether tetracarboxylic dianhydride, 1,2,3,4-cyclobutane tetracarboxylic dianhydride, pyromellitic dianhydride, bis(3,4-dicarboxyphenyl)ether dianhydride, bis(3,4-dicarboxyphenyl)sulfide dianhydride, bis(3,4-dicarboxyphenyl)sulfone dianhydride, bis(3,4-dicarboxyphenyl) methane dianhydride, 2,2-bis(3,4-dicarboxyphenyl) propane dianhydride, 2,2-bis(3,4-dicarboxyphenyl)-1,1,1,3,3,3-hexafluoropropane dianhydride, 1,2,3,4-cyclopentanetetracarboxylic dianhydride, 1,2,4,5-cyclohexanetetracarboxylic dianhydride, bicyclo[2.2.1]heptane-2,3,5,6-tetracarboxylic dianhydride, bicyclo[2.2.2]octane-2,3,5,6-tetracarboxylic dianhydride or a combination thereof, preferably including 3,3′,4,4′-diphenyl ether tetracarboxylic dianhydride, bicyclo[2.2.2]oct-7-ene-2,3,5,6-tetracarboxylic dianhydride or a combination thereof, wherein, 3,3′,4,4′-diphenyl ether tetracarboxylic dianhydride is preferred.

### Preparation of (A) Polyimide Resin

The preparation of the (A) polyimide resin can comprise at least two stages: a (A1) polymerization reaction and a (A2) dehydration ring-closure reaction. In the (A1) polymerization reaction, a polyamic acid polymer is formed by a polymerization reaction of the (a) diamine and the (b) tetracarboxylic dianhydride, and in the (A2) dehydration ring-closure reaction, an amide acid functional group in the polyamic acid polymer is transformed into an imide functional group (i.e., imidization) through the dehydration ring-closure reaction to obtain a polyimide resin containing the imide functional group. The environment, conditions and other reactants for preparing the (A) polyimide resin will be further explained below.

### Environment

The (A1) polymerization reaction and the (A2) dehydration ring-closure reaction can be carried out in an environment in which a solvent exists. That is, a preparation material of the (A) polyimide resin can further include a (c) solvent. The (c) solvent can be a polar solvent, including but not limited to N-methylpyrrolidone, γ-butyrolactone, dimethyl acetamide, methylformamide, diethylacetamide, 1,3-dimethyl-2-imidazolidinone, N-methylcaprolactam, hexamethyl phosphoric triamide. The listed (c) solvents and other solvents can be selected according to requirements, and can be used alone or in combination. For example, N-methylpyrrolidone is selected based on the requirements, for example, the solubility to a reactant (e.g., other preparation materials). In some embodiments of the present invention, a weight % of the (c) solvent in the (A1) polymerization reaction can be 15-45 wt %, and preferably 20-35 wt % relative to a total weight of the (a) diamine, the (b) tetracarboxylic dianhydride and the (c) solvent.

### Condition

In some embodiments of the present invention, the (A1) polymerization reaction can be carried out under a temperature condition of, for example, 50-80° C. for 3-6 hours. The (A2) dehydration ring-closure reaction can be carried out by a high temperature dehydration ring-closure method or a chemical dehydration ring-closure method. In some embodiments of the present invention, the high-temperature dehydration ring-closure method can be carried out at 250-350° C. for 3-6 hours, and the chemical dehydration ring-closure method can be carried out at 160-180° C. for 3-6 hours.

### Other Reactants

In some embodiments of the present invention, the reactants of the (A1) polymerization reaction can further include a (d) blocking agent for controlling the molecular weight of the polyimide resin. There is no limitation on the (d) blocking agent, and the blocking agent can include, but not limited to 3-aminophenol, phthalic anhydride, maleic anhydride, nadic acid, cyclohexanedicarboxylic anhydride, 3-hydroxyphthalic anhydride, 3-carboxyphenol, 4-carboxyphenol, 3-carboxythiophenol, 4-carboxythiophenol, 1-hydroxy-7-carboxynaphthalene, 1-hydroxy-6-carboxynaphthalene, 1-hydroxy-5-carboxynaphthalene, 1-mercapto-7-carboxynaphthalene, 1-mercapto-6-carboxynaphthalene, 1-mercapto-5-carboxynaphthalene, 3-carboxybenzenesulfonic acid, 4-carboxybenzenesulfonic acid, or a combination thereof. The reactants of the (A2) dehydration ring-closure reaction can further include a (e) dehydrating agent and a (f) catalyst. In terms of the chemical dehydration ring-closure method, in some embodiments of the present invention, the (e) dehydrating agent is, for example, an anhydride such as acetic anhydride, propionic anhydride, trifluoroacetic anhydride, etc., but the present invention is not limited thereto, and other dehydrating agents can also be selected according to requirements. The (f) catalyst can be a tertiary amine, e.g., 1-ethylpiperidine, triethylamine, pyridine, lutidine, but the present invention is not limited thereto, and other catalysts can also be selected according to requirements.

In addition to the aforementioned (a) diamine and (b) tetracarboxylic dianhydride, in some embodiments of the present invention, other diamines and tetracarboxylic dianhydrides can also be appropriately selected according to requirements. For example, according to the disclosures of publications Nos. TW202128837A, TW202128842A, TW202233722A, US2021/0223699A1, US2022/0275205A1 and publications Nos. CN114957660A, CN113219796A and the like patent applications, other diamines, tetracarboxylic dianhydrides are selected as the (a) diamine and the (b) tetracarboxylic dianhydride, and reacted to obtain the (A) polyimide resin. Furthermore, regarding the preparation of the (A) polyimide resin, in some embodiments of the present invention, in addition to the aforementioned environment, conditions, and other reactants, without violating the disclosure herein, the (A) polyimide resin can also be prepared based on the disclosures of the aforementioned patent applications.

### (B) Photo Active Compound (PAC)

The (B) photo active compound is preferably a compound having a quinone diazide group, e.g., quinone diazide sulfonic acid, a quinone diazide sulfonic acid derivative or a combination thereof, or other substances photoactive to a I-line light source. The (B) photo active compound is preferably a substance that can greatly increase a contrast ratio in an alkali dissolution rate between an exposed region and a non-exposed region of the positive photoresist composition during a positive photoresist patterning process, which helps to prepare a positive photoresist film with high resolution. There is no particular limitation on the compound having a quinone diazide group, and in some embodiments of the present invention, it is usually naphthoquinonediazide sulfonyl chloride (e.g., 1,2-naphthoquinonediazide-5-sulfonyl chloride, 1,2-naphthoquinonediazide-4-sulfonyl chloride, etc.) or benzoquinonediazide sulfonyl chloride, etc. In some embodiments of the present invention, for example, the (B) photo active compound can be obtained by reacting a quinone diazide compound containing an acyl chloride with a low-molecular or high-molecular compound, and the low-molecular or high-molecular compound has a functional group capable of condensation reaction with the quinone diazide compound containing an acyl chloride. In some embodiments of the present invention, the functional group capable of condensation reaction with the quinonediazide compound containing an acyl chloride is mainly a hydroxyl group (hereinafter referred to as a hydroxyl compound), which can include but not limited to hydroxybenzophenones (e.g., hydroquinone, resorcinol, 2,4-dihydroxybenzophenone, 2,3,4-trihydroxybenzophenone, 2,4,6-trihydroxybenzophenone, 2,4,4′-trihydroxybenzophenone, 2,3,4,4′-tetrahydroxybenzophenone, 2,2′,4,4′-tetrahydroxybenzophenone, 2,2′,3,4,6′-pentahydroxybenzophenone, etc.), hydroxyphenylalkanes (e.g., bis(2,4-dihydroxyphenyl) methane, bis(2,3,4-trihydroxyphenyl) methane, bis(2,4-dihydroxyphenyl) propane, etc.), hydroxytriphenylmethanes (e.g., 4,4′-3″,4″-tetrahydroxy-3,5,3′,5′-tetramethyltriphenylmethane, 4,4′,2″,3″,4″-pentahydroxy-3,5,3′,5′-tetramethyltriphenylmethane, etc.), and can be used alone or in combination. Specific examples of the (B) photo active compound include, for example, PAC1 and PAC2 (described hereafter).

### (C) Solvent

There is no particular limitation on the (C) solvent. Preferably, the (C) solvent is a (c) solvent used when the (A) polyimide resin is synthesized. Specific examples of (C) the solvents include, but are not limited to, N-methylpyrrolidone, γ-butyrolactone, γ-butyrolactam, 4-hydroxy-4-methyl-2-pentanone, ethylene glycol monomethyl ether, butyl lactate, butyl acetate, methyl methoxy propionate, ethyl ethoxy propionate, ethylene glycol methyl ether, ethylene glycol ethyl ether, ethylene glycol n-propyl ether, ethylene glycol isopropyl ether, ethylene glycol n-butyl ether, ethylene glycol dimethyl ether, ethylene glycol ethyl ether acetate, diethylene glycol dimethyl ether, diethylene glycol diethyl ether, diethylene glycol monomethyl ether, diethylene glycol monoethyl ether, diethylene glycol monomethyl ether acetate, diethylene glycol monoethyl ether acetate, N,N-dimethylformamide, N,N-dimethylacetamide, or a combination of the aforementioned solvents.

In addition to the (A) polyimide resin, the (B) photo active compound and the (C) solvent, the positive photoresist composition can further comprise an (D) additive under the premise of not affecting the efficacy of the present invention. There is no limitation on the (D) additive, and it can be appropriately selected according to requirements. The (D) additive can include, for example, a (D-1) leveling agent for suppressing generation of stripes and increasing film thickness uniformity, an (D-2) adhesion promoter for improving the adhesion between the photoresist composition and the substrate, and a (D-3) ultraviolet light absorber for preventing a standing wave effect caused by light reflection, but not limited thereto. For example, the (D) additive can further include an antioxidant, an anti-aging agent, and an inorganic particle with a light-scattering effect.

The following Table 1 and Examples 1-4 illustrate the preparation of and preparation materials of the (A) polyimide resin of the present invention. The following Table 2-1 and Examples 5-11 illustrate the composition and preparation of the positive photoresist composition of the present invention. The following Table 2-2 and Comparative Examples 1-4 serve as controls for Examples 5-11.

### Example 1

The preparation materials of the (A) polyimide resin in Example 1 are as shown in Table 1. Into a 1000 ml three-necked round bottom flask into which nitrogen was introduced and equipped with a mechanical stirrer, added are the (a-1) diamine, the (a-2) diamine, the (a-3) diamine, the (a-4) diamine and the (b) tetracarboxylic dianhydride, including 8.981 g (0.036 mol) of 1,3-bis(3-aminopropyl)-1,1,3,3-tetramethyldisiloxane, 59.340 g (0.015 mol) of 2,2′-Bis[4-(4-aminophenoxy)phenyl]propane, 37.340 g (0.0145 mol) of 2,2-bis(3-amino-4-hydroxyphenyl) propane, 7.236 g (0.036 mol) of 3,4-diaminodiphenyl ether and 112.103 g (0.360 mol) of 3,3′,4,4′-diphenyl ether tetracarboxylic dianhydride. Then, it is added with 673.200 g of N-methylpyrrolidone as the (C) solvent, and stirred at 70° C. for 4 hours. Then, it is further added with 1.800 g of 1-ethylpiperidine as the (f) catalyst, heated to a temperature of 180° C. and stirred for 4 hours. Then, it is cooled to obtain a polyimide resin solution. The ratio of the four diamine monomers, the (a-1) diamine: the (a-2) diamine: the (a-3) diamine: the (a-4) diamine is 0.1:0.4:0.4:0.1.

### Examples 2-4

The preparation materials of each (A) polyimide resin and the proportions of various diamine monomers thereof in Examples 2-4 are as shown in Table 1. The preparation of each (A) polyimide resin of Examples 2-4 is the same as that of Example 1.

TABLE 1
the (A) polyimide resins of Examples 1-4

| | | | Example | Example | Example | Example |
|---|---|---|---|---|---|---|
| | | Unit | 1 | 2 | 3 | 4 |
| (a) | 1,3-bis(3-aminopropyl)- | Mole | 0.036 | 0.035 | 0.067 | 0.069 |
| diamine | 1,1,3,3-tetramethyldisiloxane | number | | | | |
| | | Molar | 0.1 | 0.1 | 0.1 | 0.1 |
| | | ratio | | | | |
| | 2,2′-Bis[4-(4- | Mole | 0.015 | 0.210 | 0 | 0 |
| | aminophenoxy)phenyl]propane | number | | | | |
| | | Molar | 0.4 | 0.6 | 0 | 0 |
| | | ratio | | | | |
| | 2,2-bis(3-amino-4- | Mole | 0.0145 | 0.070 | 0.334 | 0.344 |
| | hydroxyphenyl)propane | number | | | | |
| | | Molar | 0.4 | 0.2 | 0.5 | 0.5 |
| | | ratio | | | | |
| | 3,4-diaminodiphenyl | Mole | 0.036 | 0.035 | 0.117 | 0.241 |
| | ether | number | | | | |
| | | Molar | 0.1 | 0.1 | 0.175 | 0.35 |
| | | ratio | | | | |
| | 3,3′-dicarboxyl-4,4′- | Mole | 0 | 0 | 0.117 | 0 |
| | diaminodiphenylmethane | number | | | | |
| | | Molar | 0 | 0 | 0.175 | 0 |
| | | ratio | | | | |
| | 6,6′-bisamino-3,3′- | Mole | 0 | 0 | 0.067 | 0.069 |
| | methoxydibenzoic acid | number | | | | |
| | | Molar | 0 | 0 | 0.1 | 0.1 |
| | | ratio | | | | |
| (b) | 3,3′,4,4′-diphenyl ether | Mole | 0.360 | 0.345 | 0 | 0 |
| tetracarboxylic | tetracarboxylic | number | | | | |
| dianhydride | dianhydride | Molar | 1 | 1 | 0 | 0 |
| | | ratio | | | | |
| | bicyclo[2.2.2]oct-7-ene- | Mole | 0 | 0 | 0.667 | 0.688 |
| | 2,3,5,6-tetracarboxylic | number | | | | |
| | dianhydride | Molar | 0 | 0 | 1 | 1 |
| | | ratio | | | | |
| (c) | N-methylpyrrolidone | Grams | 673.200 | 673.200 | 0 | 0 |
| solvent | γ-butyrolactone | Grams | 0 | 0 | 614.840 | 647.200 |
| (f) | 1-ethylpiperidine | Grams | 1.800 | 1.800 | 2.660 | 2.660 |
| catalyst | | | | | | |

### Example 5

The composition of the positive photoresist composition of Example 5 is shown in Table 2-1. In Example 5, 37.46 parts by weight of the (A) polyimide resin of Example 1 (with its solid content of 34.7 wt %) and 2.60 parts by weight of the (B) photo active compound PAC1 with a quinone diazide group are taken, added with 84.35 parts by weight of N-methylpyrrolidone as the (C) solvent, mixed under stirring, and then filtered with a 0.1 micron filter to formulate the positive photoresist composition.

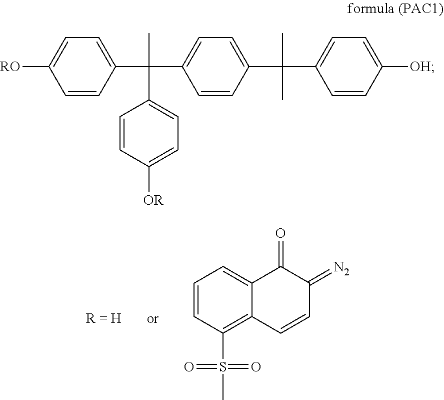

wherein, preferably, at least one R has a quinone diazide group.

### Examples 6-11

The composition of each positive photoresist composition in Examples 6-11 is shown in Table 2-1. The preparation of each positive photoresist composition in Examples 6-11 is roughly the same as that of Example 5, except that the use amount of the (A) polyimide resin, the use amount of the (B) photo active compound, and the use amount of the (C) solvent could still be different from those in Example 5.

TABLE 2-1
Positive photoresist compositions of Examples 5-11

| | | | (B) photo | | (C) solvent | | |
|---|---|---|---|---|---|---|---|
| | (A) polyimide | | active | | | | Propylene |
| | resin | | compound | | | | glycol |
| | | Solid | (PAC) | | | | methyl |
| | | weight | Type | | N- | γ- | ether |
| | | percentage | (chemical | | methylpyrrolidone | butyrolactone | acetate |
| | Source | (wt %) | formula) | (wt %) | (wt %) | (wt %) | (wt %) |
| Example | Example | 13.05 | PAC1 | 2.60 | 84.35 | — | — |
| 5 | 1 | | | | | | |
| Example | Example | 10.55 | PAC1 | 5.25 | 84.20 | — | — |
| 6 | 1 | | | | | | |
| Example | Example | 8.80 | PAC1 | 7.04 | 84.16 | — | — |
| 7 | 1 | | | | | | |
| Example | Example | 10.55 | PAC2 | 5.25 | 84.20 | — | — |
| 8 | 1 | | | | | | |
| Example | Example | 10.55 | PAC1 | 5.25 | 84.20 | — | — |
| 9 | 2 | | | | | | |
| Example | Example | 10.55 | PAC1 | 5.25 | — | 84.20 | — |
| 10 | 3 | | | | | | |
| Example | Example | 10.55 | PAC1 | 5.25 | — | 84.20 | — |
| 11 | 4 | | | | | | |

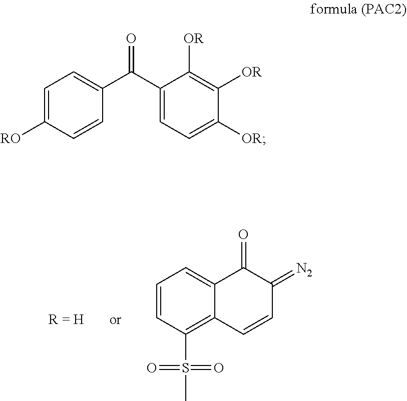

wherein, preferably, at least one R has a quinone diazide group.

### Comparative Examples 1-4

The preparation of each positive photoresist composition in Comparative Examples 1-4 is the same as that in Example 5, except that in Comparative Examples 1-3, the used resin is a Novolac resin commonly used in a traditional positive photoresist, and its structure could be shown in the figure below,

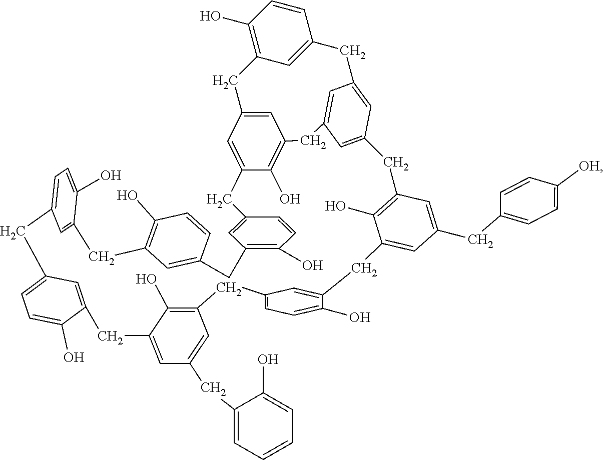 [SMILES: Oc1ccc(Cc2cc3c(O)c(c2)Cc2cc(ccc2O)Cc2cc(Cc4ccccc4O)cc(c2O)Cc2cc(ccc2O)Cc2ccc(O)c(c2)Cc2cc(ccc2O)Cc2cc(ccc2O)Cc2cc4cc(c2O)Cc2cc(cc(c2)C3)Cc2ccc(O)c(c2)C4)cc1]

the used solvent is PGMEA (propylene glycol methyl ether acetate), and the composition thereof is shown in Table 2-2 in details. In Comparative Example 4, the used resin was a PHS type resin commonly used in a traditional amplified positive photoresist, and its structure could be shown in the figure below, where x is, for example, 60, y is, for example, 20, and z is, for example, 20:

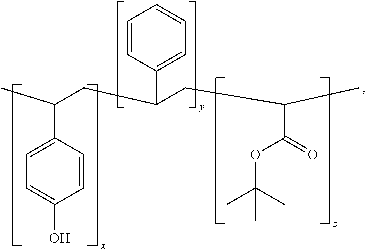

the used photo active material is a photoacid generator (PAG) structure as shown in the figure below:

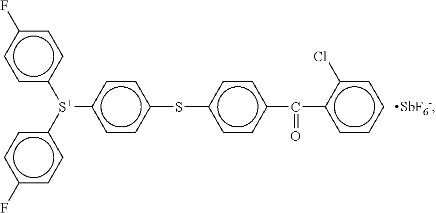

the used solvent is PGMEA (propylene glycol methyl ether acetate), and is shown in Table 2-2 in details.

TABLE 2-2
Positive photoresist compositions of Comparative Examples 1-4

| | | | | | Solvent | | |
|---|---|---|---|---|---|---|---|
| | | | | | | | Propylene |
| | Resin | | | | | | glycol |
| | | Solid | | | | | methyl |
| | | weight | Photo active | | N- | γ- | ether |
| | | percentage | material | | methylpyrrolidone | butyrolactone | acetate |
| | Source | (wt %) | Type | (wt %) | (wt %) | (wt %) | (wt %) |
| Comparative | Novolac | 13.05 | PAC1 | 2.60 | — | — | 84.35 |
| Example 1 | | | | | | | |
| Comparative | Novolac | 10.55 | PAC1 | 5.25 | — | — | 84.20 |
| Example 2 | | | | | | | |
| Comparative | Novolac | 8.80 | PAC1 | 7.04 | — | — | 84.16 |
| Example 3 | | | | | | | |
| Comparative | PHS type | 15.50 | PAG | 0.30 | — | — | 84.20 |
| Example 4 | Copolymer | | | | | | |

### Positive Photoresist Film

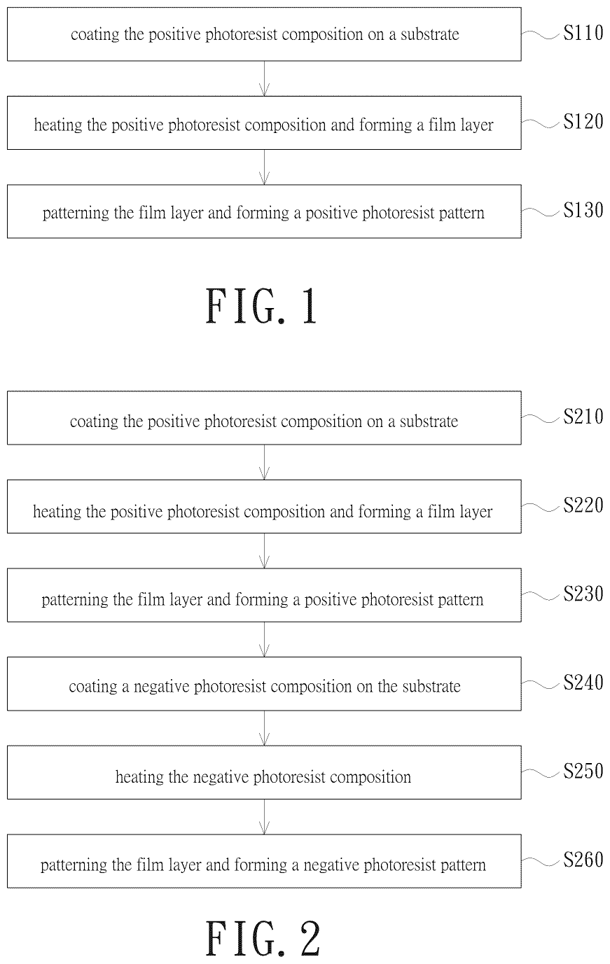

The positive photoresist composition of the present invention can be used in the preparation of a positive photoresist film and in a positive photoresist pattern lithography process. As shown in FIG. 1, the positive photoresist pattern lithography process of the present invention comprises step S110: coating the positive photoresist composition as mentioned above on a substrate; step S120: heating the positive photoresist composition and forming a film layer; and step S130: patterning the film layer and forming a positive photoresist pattern. In some embodiments of the present invention, the step S120 further includes baking at 100-130° C., for example, baking on a hot plate of 100° C. The step S130 further comprises exposing and developing the film layer. The coating, heating, exposure, development, etc. of the positive photoresist pattern lithography process would be further described hereafter.

### Coating

The coating manner is not limited in the present invention, but for example, the coating manner can be such as spin coating, roller coating, screen coating, curtain coating, dip coating, or spray coating, but is not limited thereto. The substrate can be, for example, a silicon substrate, glass, or ITO glass, and any desired film layer could have been formed on the substrate.

### Heating

In some embodiments of the present invention, baking at 100-130° C. can also be used for evaporating the (C) solvent in the composition.

### Exposure

Exposure further comprises configuring a photomask on the substrate on which the film layer is formed, and exposing the film layer under the photomask through actinic rays. Actinic rays are, for example, X-rays, electron-beam rays, ultraviolet light rays, visible light rays, or other light sources that can serve as actinic rays. The energy used for exposure could affect the thickness of the positive photoresist film and the resolution of the pattern (described hereafter).

### Development

In some embodiments of the present invention, an alkaline aqueous developer is used for developing to remove the exposed portion of the positive photoresist film layer to obtain the pattern (picture). The alkaline aqueous developer includes an alkaline aqueous solution. The alkaline aqueous solution can be, for example, an aqueous solution of an inorganic base (e.g., potassium hydroxide, or sodium hydroxide), a primary amine (e.g., ethylamine), a secondary amine (e.g.,: diethylamine), a tertiary amine (e.g., triethylamine), or a quaternary ammonium salt (e.g.,: tetramethylammonium hydroxide), wherein the aqueous solution containing tetramethylammonium hydroxide is preferred. The developing manner is not limited in the present invention, but for example, the developing can be accomplished by soaking, spraying or liquid coating or other known manners. Preferably, the positive photoresist film pattern obtained by developing can then be washed with deionized water, and subsequently dried with an air gun. The development time could affect the thickness of the positive photoresist film and the resolution of the pattern (described hereafter).

Example 12 exemplified the preparation of positive photoresist films using the compositions of Examples 5-11 and Comparative Examples 1-4. The following Table 3-1 and Example 13 illustrated an evaluation method of the pattern of the positive photoresist film, and the attainable preferred pattern resolution of each positive photoresist film prepared with the compositions of Examples 5-11 and Comparative Examples 1-4. The following Table 3-1 and Example 14 illustrated solvent resistance tests and test results of the positive photoresist films prepared from the compositions of Examples 5-11 and Comparative Examples 1-4.

### Example 12

In the preparation of the positive photoresist films of Example 12, each positive photoresist composition of Examples 5-11 and Comparative Examples 1-4 is coated on a substrate by a spin coating method, and baked on a hot plate of 100° C. for 360 seconds, and then exposed with a Canon FPA 5500iZa exposure machine. The exposure energy is 1,000-5,000 J/m², and Focus=0. Subsequently, development is performed using a developing solution of 0.3% TMAH (tetramethylammonium hydroxide) for 30 seconds. The obtained positive photoresist film has a film thickness of 0.6 μm and a pattern resolution of 0.6 μm. Moreover, by testing various different exposure energies and developing times, the attainable minimum pattern resolution of each positive photoresist film with the thickness of 0.6 microns can be obtained.

### Example 13

In the pattern evaluation method of Example 13, a field emission scanning electron microscope (FESEM) SU-8010 is used for confirming the resolution of the positive photoresist film obtained after development of each composition in Examples 5-11 and Comparative Examples 1-4, and testing the attainable preferred pattern resolution of the positive photoresist film with the thickness of 0.6 microns under various different exposure energies and developing conditions. It is better when the resolution value is smaller.

### Example 14

In the solvent resistance test of Example 14, a mixed solvent of PGMEA and OK73 (propylene glycol methyl ether/propylene glycol methyl ether acetate=70/30) is selected to test the solvent resistance of the positive photoresist film. PGMEA and OK73 are also commonly used solvents for the negative photoresist composition. The positive photoresist films obtained after development of the compositions of Examples 5-11 and Comparative Examples 1-4 are taken, and spin coated with 6 ml of the mixed solvent of PGMEA and OK73, respectively. After that, the field emission scanning electron microscope (FESEM) SU-8010 is used for observing whether the profile of the positive photoresist film pattern is complete, or whether there is disappearance, deformation, incompletion or the like conditions. Those that have disappeared or are incomplete are unqualified and marked as ×. Those that have not disappeared or are not incomplete are qualified and marked as ∘. If the positive photoresist film obtained from the composition does not disappear or is not incomplete, it meant that the composition and the positive photoresist film thereof are suitable for the negative photoresist pattern lithography process (described hereafter).

TABLE 3-1

| | Minimum | PGMEA | OK73 |
|---|---|---|---|
| | resolution (μm) | Resistance Test | Resistance Test |
| Example 5 | 0.6 | ∘ | ∘ |
| Example 6 | 0.5 | ∘ | ∘ |
| Example 7 | 0.4 | ∘ | ∘ |
| Example 8 | 0.6 | ∘ | ∘ |
| Example 9 | 0.4 | ∘ | ∘ |
| Example 10 | 0.4 | ∘ | ∘ |
| Example 11 | 0.4 | ∘ | ∘ |
| Comparative | 0.6 | x | x |
| Example 1 | | | |
| Comparative | 0.5 | x | x |
| Example 2 | | | |
| Comparative | 0.4 | x | x |
| Example 3 | | | |
| Comparative | 0.4 | x | x |
| Example 4 | | | |

### Negative Photoresist Pattern Lithography Process and Negative Photoresist Pattern Manufactured Therefrom

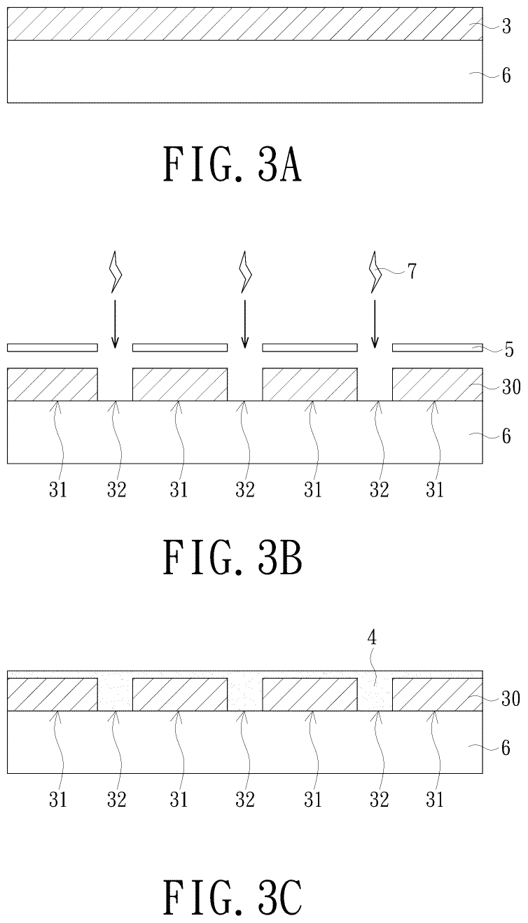

The positive photoresist composition of the present invention is also suitable for the negative photoresist pattern lithography process. The present invention further provides a negative photoresist pattern lithography process method. As shown in FIG. 2, the negative photoresist pattern lithography process comprises step S210: coating the positive photoresist composition as mentioned above on a substrate; step S220: heating the positive photoresist composition and forming a film layer; step S230: patterning the film layer and forming a positive photoresist pattern; step S240: coating a negative photoresist composition on the substrate; step S250: heating the negative photoresist composition; and step S260: patterning the film layer and forming a negative photoresist pattern. Step S210 is substantially equivalent to step S110, step S220 is substantially equivalent to step S120, and step S230 is substantially equivalent to step S130. That is, the negative photoresist pattern lithography process of the present invention uses the positive photoresist composition of the present invention and the positive photoresist pattern manufactured therefrom. It is further explained as follows.

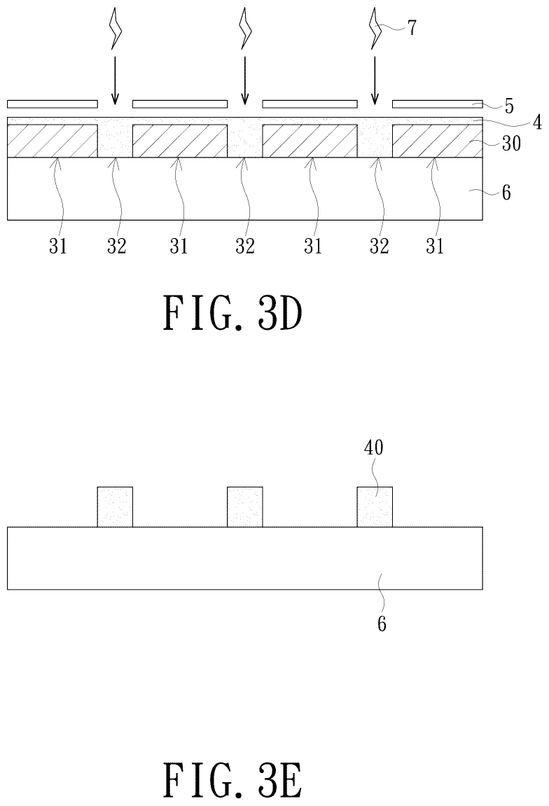

Please refer to FIGS. 3A-3E. FIGS. 3A-3B are schematic diagrams of steps S210-S230. As shown in FIG. 3B, step S230 further comprises allowing the positive photoresist pattern 30 to define a first region 31 and a second region 32 on the substrate by a photomask 5. FIGS. 3C-3E are schematic diagrams of steps S240-S260. As shown in FIG. 3C, step S240 further comprises distributing the negative photoresist composition 4 in the second region 32. In some embodiments, as shown in FIG. 3C, step S240 further comprises distributing the negative photoresist composition 4 in the first region 31, wherein the negative photoresist composition 4 distributed in the first region 31 covers the positive photoresist pattern 30. As long as the solvent contained in the negative photoresist composition is different from the aforementioned (C) solvent and/or (c) solvent, the negative photoresist composition used in steps S240-S260 is not limited in the present invention in principle. The manner of coating the negative photoresist composition 4 can be referred to those mentioned above, and would not be repeated here anymore. Moreover, the manner of coating the negative photoresist composition 4 could further affect whether the negative photoresist composition 4 is distributed in the first region 31.

In view of the above, in the embodiment in which the negative photoresist composition 4 is distributed in the first region 31, the negative photoresist composition 4 has different distribution heights in the first region 31 and the second region 32, and its distribution height can be different based on the positive photoresist pattern 30. For example, when the thickness of the positive photoresist pattern 30 is greater, the positive photoresist pattern 30 surrounding the second region 32 is higher, and the height of the negative photoresist composition 4 in the second region 32 could be higher. Preferably, the height of the negative photoresist composition 4 in the first region 31 is smaller than that in the second region 32.

In some embodiments of the present invention, step S250 further includes baking at 80-120° C., and step S260 further comprises exposing and developing the film layer. As shown in FIG. 3D, the exposure position in step S260 is the same as that in step S230. That is, the negative photoresist composition 4 distributed in the second region 32 is exposed. Therefore, as shown in FIG. 3E, the unexposed portion of the negative photoresist composition after development will be removed to obtain the negative photoresist pattern 40, wherein the positive photoresist pattern 30 and the unexposed negative photoresist composition 4 will also be removed during development. As shown in FIGS. 3D-3E, the unexposed negative photoresist composition has a smaller height because of the positive photoresist pattern 30 underneath, so the volume to be removed is smaller and the time required for development is less, thereby reducing the probability of swelling, scum, undercut and the like conditions of the negative photoresist pattern 40 and being helpful to improve the quality and resolution of the negative photoresist pattern 40. For the rays used for exposure and the developer used for development in step S260, please refer to the above, and it would not be repeated here anymore.

Example 15 exemplifies the preparation of negative photoresist patterns using the compositions of Examples 5-11 and Comparative Examples 1-4, and the evaluation of the prepared negative photoresist patterns.

### Example 15

In the preparation of the negative photoresist pattern in Example 15, the positive photoresist film patterns obtained after development of respective compositions of Examples 5-11 and Comparative Examples 1-4 are taken and used for spin coating of 6 cc with the negative photoresist respectively. In some embodiments of the present invention, the negative photoresist consists of 12 wt % of an acrylic resin, 6 wt % of a polymerizable monomer, 2 wt % of a photoinitiator, and 80 wt % of a PGMEA solvent. Then, it is observed whether there is color pollution on the film face. Subsequently, exposure is performed with a photomask to cause a cross-linking reaction of the negative photoresist. Then, development is conducted with the developing solution of 0.3% TMAH for 80 seconds to obtain the negative photoresist pattern, and at the same time the positive photoresist film pattern on the substrate is completely removed to leave only the negative photoresist pattern on the substrate. Next, the field emission scanning electron microscope (FESEM) SU-8010 is used for observing whether the profile of the negative photoresist pattern is complete, or whether there is deformation, color pollution, residues, and the like conditions. If there is deformation, color pollution, residues, and the like conditions, it is unqualified and marked as ×. If the profile is complete without deformation, color pollution, residues, and the like conditions, it is qualified and marked as ∘. The results are shown in Table 3-2 below.

TABLE 3-2

| | Evaluation of Negative |
|---|---|
| | Photoresist Pattern |
| Example 5 | ∘ |
| Example 6 | ∘ |
| Example 7 | ∘ |
| Example 8 | ∘ |
| Example 9 | ∘ |
| Example 10 | ∘ |
| Example 11 | ∘ |
| Comparative | x |
| Example 1 | |
| Comparative | x |
| Example 2 | |
| Comparative | x |
| Example 3 | |
| Comparative | x |
| Example 4 | |

According to Examples 12-15 and Tables 3-1 and 3-2, the positive photoresist film pattern manufactured from the positive photoresist composition of the embodiment of the present invention can reach a high resolution of 0.4 microns, and the developed film pattern has good solvent resistance. Moreover, the film pattern is not dissolved and the condition of color pollution does not occur if the negative photoresist is coated on the positive photoresist film pattern. In contrast, for the positive photoresist film patterns prepared from the positive photoresist compositions of Comparative Examples 1-4, although its resolution can also reach 0.4 microns, it has poor solvent resistance, and after being coated with the negative photoresist and the development, the film patterns are dissolved and cause severe color pollution. Therefore, the positive photoresist composition of the present invention is suitable for the negative photoresist pattern lithography process method of the present invention, and for obtaining the negative photoresist pattern. The negative photoresist pattern lithography process method of the present invention improves the swelling, scum, undercut and the like conditions of the conventional negative photoresist pattern, and helps to obtain a negative photoresist pattern with high resolution.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A positive photoresist composition, comprising:
a (A) polyimide resin which is obtained by conducting a polymerization reaction of a (a) diamine and a (b) tetracarboxylic dianhydride, and has a structural unit of formula (1) 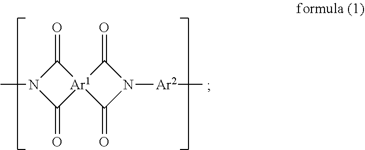
a (B) photo active compound; and
a (C) solvent;
wherein, Ar¹ in the formula (1) is a tetravalent organic group, Ar² is a bivalent organic group, and Ar¹ is a group of formula (B-1), formula (B-2), formula (B-3) or a combination thereof 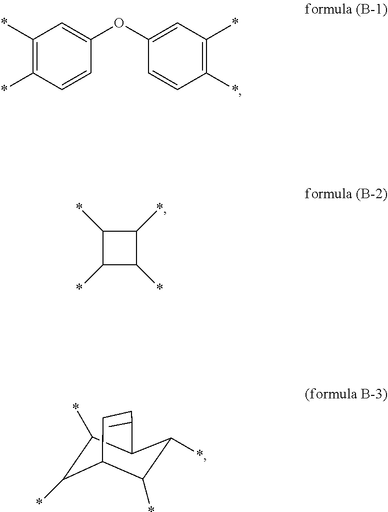
* indicates a bonding position;
Ar² in the formula (1) includes a group of formula (A-1), formula (A-2) or a combination thereof 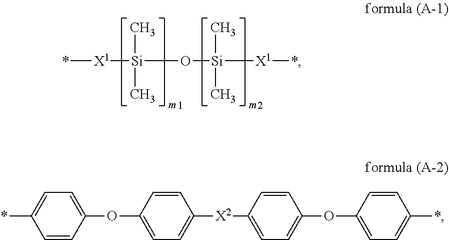
wherein, m1 and m2 in the formula (A-1) are each an integer of 1-3, and X¹ is each an alkylene or phenylene group with a carbon number of 1 to 5; wherein, when X¹ is an alkylene group with the carbon number of 1 to 5, any —CH₂— in the alkylene group with a carbon number of 1 to 5 can be substituted by —NH—; X² in the formula (A-2) is a hydrocarbyl group with a carbon number of 1 to 10, —O—, —S—, —SO₂—, —NH—, —C(CF₃)₂— or

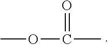

2. The photoresist composition according to claim 1, wherein Ar² further includes a group of formula (A-3), formula (A-4), formula (A-5) or a combination thereof 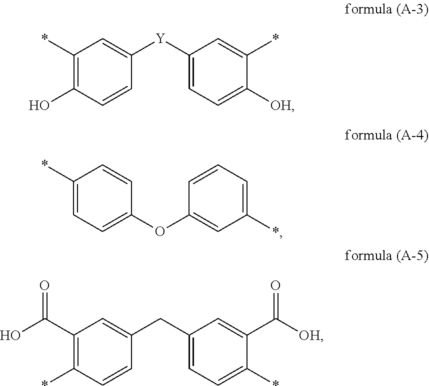
wherein, Y in the formula (A-3) is —C(CH₃)₂—, —C(CF₃)₂—, —CH₂—, —O—, —S— or —SO₂—; and * indicates a bonding position.

3. The photoresist composition according to claim 1, wherein the (a) diamine includes a (a-1) diamine and a (a-2) diamine; the (a-1) diamine is a diamine having a silicon-oxygen bond, and is a compound of formula (I-1); and the (a-2) diamine is a diamine having four benzene rings, and is a compound of formula (I-2) 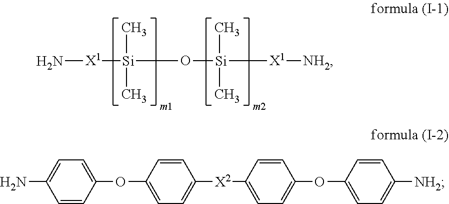
wherein, m1 and m2 in the formula (I-1) are each an integer of 1-3, and X¹ is each an alkylene or phenylene group with a carbon number of 1 to 5; wherein, when X¹ is an alkylene group with a carbon number of 1 to 5, any —CH₂— in the alkylene group with the carbon number of 1 to 5 can be substituted by —NH—; X² in the formula (I-2) is a hydrocarbyl group with a carbon number of 1 to 10, —O—, —S—, —SO₂—, —NH—, —C(CF₃)₂— or

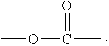

4. The positive photoresist composition according to claim 3, wherein the (a) diamine further includes a (a-3) diamine; and the (a-3) diamine is a diamine having a phenol structure, and is a compound of formula (I-3) 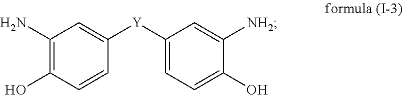
wherein, Y in the formula (I-3) is —C(CH₃)₂—, —C(CF₃)₂—, —CH₂—, —O—, —S— or —SO₂—.

5. The positive photoresist composition according to claim 1, wherein the (A) polyimide resin has a weight average molecular weight of 5,000-50,000.

6. The positive photoresist composition according to claim 1, wherein the (B) photo active compound is quinone diazide sulfonic acid, a quinone diazide sulfonic acid derivative or a combination thereof; and when an amount of the (A) polyimide resin is 100 parts by weight, an amount of the (B) photo active compound is 10-150 parts by weight.

7. The positive photoresist composition according to claim 1, wherein the (C) solvent is N-methylpyrrolidone, γ-butyrolactone, ethyl lactate, N,N-dimethylformamide, N,N-dimethyl acetamide or a combination thereof, and the (C) solvent accounts for 50-90% by weight of the positive photoresist composition.

8. A negative photoresist pattern lithography process method, comprising:
coating the positive photoresist composition according to claim 1 on a substrate;
heating the positive photoresist composition and forming a film layer;
patterning the film layer and forming a positive photoresist pattern;
coating a negative photoresist composition on the substrate;
heating the negative photoresist composition; and
patterning the film layer and forming a negative photoresist pattern.

9. The negative photoresist pattern lithography process method according to claim 8, wherein the step of patterning the film layer and forming the positive photoresist pattern further comprises exposing and developing the film layer, the step of patterning the film layer and forming the negative photoresist pattern further comprises exposing and developing the film layer, with the positions of the two exposures being the same.

10. The negative photoresist pattern lithography process method according to claim 8, wherein the step of heating the positive photoresist composition further includes baking at 100-130° C., and the heating the negative photoresist composition further includes baking at 80-120° C.

11. The negative photoresist pattern lithography process method according to claim 8, wherein the step of patterning the film layer and forming the positive photoresist pattern further comprises allowing the positive photoresist pattern to define a first region and a second region on the substrate.

12. The negative photoresist pattern lithography process method according to claim 11, wherein the step of coating the negative photoresist composition on the substrate further comprises distributing the negative photoresist composition in the second region.

13. The negative photoresist pattern lithography process method according to claim 12, wherein the step of coating the negative photoresist composition on the substrate further comprises distributing the negative photoresist composition in the first region, wherein the negative photoresist composition distributed in the first region covers the positive photoresist pattern.

14. The negative photoresist pattern lithography process method according to claim 11, wherein the step of coating the negative photoresist composition on the substrate further comprises distributing the negative photoresist composition in the second region; and the step of patterning the film layer and forming the negative photoresist pattern further comprises exposing the negative photoresist composition distributed in the second region to form the negative photoresist pattern.

15. The negative photoresist pattern lithography process method according to claim 14, wherein the step of patterning the film layer and forming the negative photoresist pattern further comprises developing with an alkaline aqueous solution, and removing the positive photoresist pattern.

16. The negative photoresist pattern lithography process method according to claim 8, further including preparing the positive photoresist composition by using a (A) polyimide resin, a (B) photo active compound and a (C) solvent; wherein, the (A) polyimide resin has a structural unit of formula (1), and Ar¹ and Ar² are as defined in claim 1

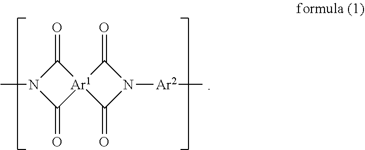

17. The negative photoresist pattern lithography process method according to claim 16, wherein the step of preparing the positive photoresist composition further comprises conducting a polymerization reaction of a (a) diamine and a (b) tetracarboxylic dianhydride to provide the (A) polyimide resin.
